(19) United States
(12) Patent Application Publication
(10) Pub. No.: US 2009/0042418 A1
(43) Pub. Date: Feb. 12, 2009

(54) Camera modular connector having metal shell having deformable tab facilitating removal of connector assemble therein

(75) Inventor: Chun-Kwan Wu, Tu-cheng (TW)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 12/221,821

(22) Filed: Aug. 6, 2008

(30) Foreign Application Priority Data
Aug. 6, 2007 (CN) 200720041421.4

(51) Int. Cl. H05K 1/00

(52) U.S. Cl. 439/81

(57) ABSTRACT

A camera modular connector (100) includes an insulative housing (1), a plurality of terminals (2) received therein, a shell (3) encircling the housing 1, and at least one pair of tab (312) extends upwardly from the shell (3) higher than the other parts of the shell (3), by curving the tab (312) the shell can be removed conveniently.

### BACKGROUND OF THE INVENTION

1. Field of the Invention

The present invention relates to a camera modular connector, and more particularly to a camera modular connector with having metal shell having deformable tab facilitating removal of connector assembled therein.

2. Description of Related Art

Pub. No. US 2006/0051986 A1 filed by Asai et al and published on Mar. 9, 2006 (hereinafter referred to as the Asai '986 application) discloses an electronic module socket provided into which camera modules of different shapes can be securely inserted. The electronic modular socket includes a socket body with an insertion portion into which an electronic module is engageably inserted and a socket engagement portion that securely engages the electronic module on inner sidewalls of the insertion portion. The electronic module has a shape suitable for securely engaging with the socket engagement portion. An electronic module smaller than the insertion portion of the socket body is engageably secured via a spacer. The spacer has an inner shape that allows the electronic module to be inserted therein and an outer shape capable of being fitted into the insertion portion of the socket body. The spacer is also provided with spacer engagement portions to engage the socket engagement portions.

Referring to FIG. 4 of the Asai '986, the fingers (23, 24) lean abut the camera modular (M). But when camera modular (M) received in the connector abatement of action needs to be removed from the connector, the shell (3) having no structure of arrangement to facilitate the removal, and thereby making the process of rework complex and difficult.

Hence, an improved connector is required to overcome the disadvantages of the prior art.

### SUMMARY OF THE INVENTION

It is an object of the present invention to provide a camera modular connector comprising a shell which has a structure of arrangement to facilitate the removal.

In order to achieve the objective above, a camera modular connector in accordance with a preferred embodiment of the present invention comprises a metallic shell assembling an insulative housing therein. The insulative housing has a plurality of terminals disposed therein. The metallic shell includes four lateral walls, two of the four lateral walls provide arms for holding a camera module therein, a deformable tab is arranged on the lateral wall between the arms. Carrying the tab, the shell can be removed from the housing easily.

Other objects, advantages and novel features of the invention will become more apparent from the following detailed description of the present embodiment when taken in conjunction with the accompanying drawings.

### BRIEF DESCRIPTION OF THE DRAWINGS

FIG. 1 is a perspective view of an camera modular connector of a preferred embodiment of the present invention;

FIG. 2 is exploded view of the present invention of FIG. 1; and

FIG. 3 is another perspective view of the camera modular connector as shown in FIG. 1, when the tab is curved.

### DETAILED DESCRIPTION OF THE INVENTION

Reference will now be made to the drawings to describe the present invention in detail.

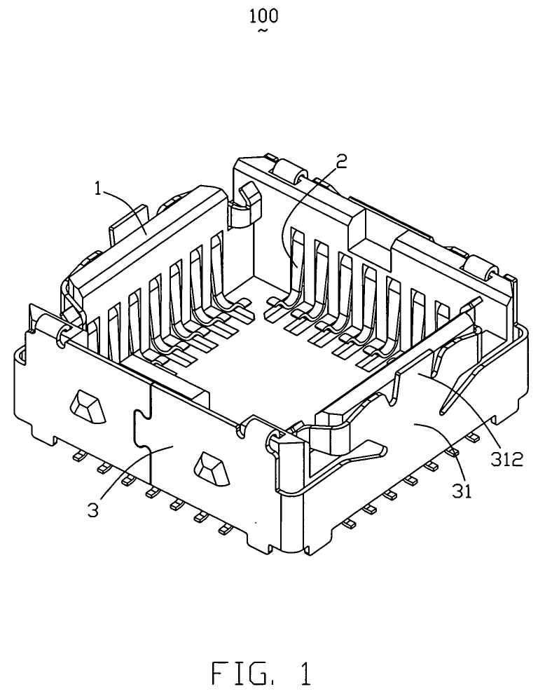

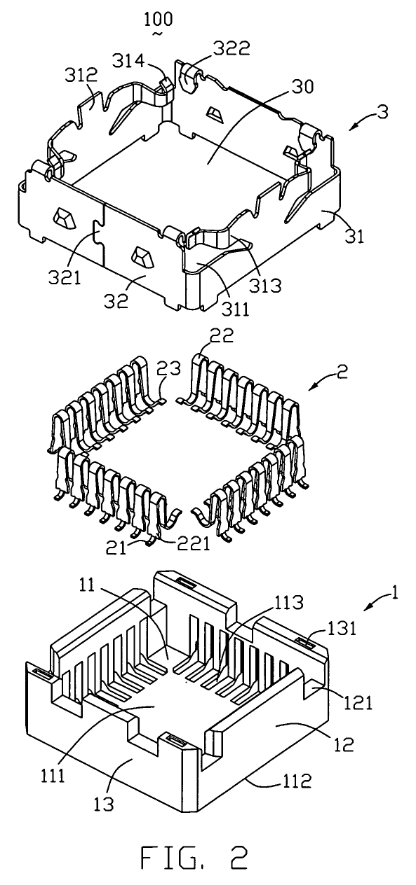

Referring to FIG. 1 to FIG. 3, the connector 100 adapt for a camera modular (not shown) includes an insulative housing 1, a plurality of conductive terminals 2 disposed in the housing 1, and a shell 3 surrounding the housing 1.

The housing 1 includes a bottom wall 11 which has a mating face 111 and a mounting face 112 opposite to the mating face 111. Two pairs of side walls 12, 13 extend from the four edges of the bottom wall 11. The four side walls 12,13 include a plurality of terminal grooves 113 disposed therein, each groove 113 respectively receives a single one of the terminals 2 therein. Each side wall 13 includes two holes 131, and each side wall 12 contains two cutouts 121 at the corner shaped by the side walls 12,13.

A plurality of terminals 2 can be positioned in the terminal grooves 113. Each terminal 2 contains a soldering portion 21, a connecting portion 22 and a contact portion 23. The soldering portion 21 can be soldered to a substrate such as a flexible flat circuit board or a flexible print circuit board, and the contact portion 23 contacts the camera modular. The terminals 2 have agnail 221 in the connecting portion 22.

The shell 3 is made of an elongate metal sheet, the two tip ends of metal sheet is combined together. The shell 3 mainly assumes to be a square frame, correspondingly to the four walls 12,13 of the housing 1, the shell 3 forms four lateral walls 31,32. The four lateral walls 31,32 define a receiving space 30 in the centre. Each lateral wall 31 has a pair of arms 313 extending inwardly to the receiving space 30. The end of the arms 313 incline upwardly, and a leading face 314 is positioned at the end of the arm 313. Each lateral wall 32 has anchor 322, the anchor 322 is inserted into the hole 131 of the housing 1 so that the housing 1 and the shell 3 could combine firmly. The leading face 314 makes the camera modular be mounted smoothly, and the arm 313 holds the camera modular in the receiving space 30. In the middle of the two arms 313, a tab 312 is located. When the shell 3 needs to be removed from the housing 1, curving the tab 312 makes the process of removing simply.

When the connector 100 is assembled, fix the terminals 2 in the terminal grooves 113 of the housing 1. Encircle the housing 1 with the shell 3, the anchor 322 of the shell is inserted into the hole 131, and the arms 313 extend inwardly through the cutout 121.

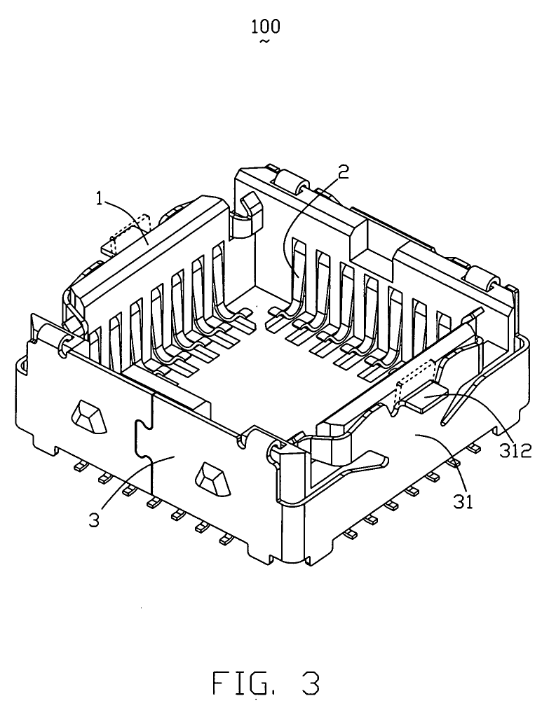

Referring to FIG. 3, when disassembled, vertically curving the tab 312, you can use your fingers or other instruments to take the shell 3 apart from the housing 1.

It will be understood that the invention may be embodied in other specific forms without departing from the spirit or central characteristics thereof.

The present examples and embodiments, therefore, are to be considered in all respects as illustrative and not restrictive, and the invention is not to be limited to the details given herein.

What is claimed is:

1. A camera modular connector, comprising:
a metallic shell having four lateral walls defining a receiving space, a pair of arms extending from a lateral wall for leading and positioning the camera module assembled therein, a deformable tab arranged on the lateral wall between the arms;
an insulative base received in the shell having a bottom wall and four side walls correspondingly to the lateral walls of the shell, each side wall defining cutouts corresponding to the arms, a number of recesses defined in the bottom and side walls;
a plurality terminals fixed in the recess having contact portion connecting the camera modular and soldering portion for attaching the modular onto a printed circuit board;
wherein said deformable tab is higher than said side wall of the insulative base.

2. The connector claimed in claim 1, wherein the arm extends from one side of the tab to the receiving space.

3. The connector claimed in claim 2, wherein the end of the arm inclines upwardly, a leading face is positioned at the end of the arm.

4. The connector claimed in claim 3, wherein the shell has at least one anchor bent from the upper side of the shell to the receiving space inserting into the housing.

5. A camera module connector assembly comprising:
a metallic shell including four side plates commonly defining a receiving cavity there among;
two of said four side plates each providing a releasable member with operation handle thereon for releasing the holding force of the releasable member and arms adjoining the operation handle for holding a camera module;
the other two of said four side plates each providing a restriction device for holding said shell;
a plurality of contacts each having one end orienting the receiving cavity, the other end extending towards outside of the receiving cavity;
wherein said operation handle is higher than other portions of the releasable member.

6. The camera modular connector claimed in claim 5, wherein the shell defines a narrow cutout located between the operation handle and other portions of the releasable member.

7. An electrical connector comprising:
an insulative housing defining a bottom wall and a plurality of side walls commonly forming a receiving cavity;
a pair of cutouts formed in a selected one of said side walls;
a plurality of passageways each facing the receiving cavity and defined in the bottom wall and the corresponding side wall;
a frame like metallic shell surrounding the housing and defining a plurality of plates covering the corresponding side walls, respectively; and
a pair of locking arms formed on a selected one of said side plates which corresponds to the side wall having said pair of cutouts thereof under a condition that each of said locking arms defines a locking head located at a distal end and extending through the corresponding cutout into the receiving cavity; wherein said selected one of the side plates further defines a handler located between the pair of locking arms so that outward deflection of the handler results in outward movement of the locking heads of both the locking arms leaving the receiving cavity.
